(19) United States
(12) Patent Application Publication
(10) Pub. No.: US 2025/0273629 A1
(43) Pub. Date: Aug. 28, 2025

(54) SEMICONDUCTOR PACKAGE

(71) Applicant: SAMSUNG ELECTRONICS CO., LTD., SUWON-SI (KR)

(72) Inventors: Manhee Han, Suwon-si (KR); Junghyun Roh, Suwon-si (KR); Jaeyoung Hong, Suwon-si (KR)

(21) Appl. No.: 19/050,717

(22) Filed: Feb. 11, 2025

(30) Foreign Application Priority Data
Feb. 23, 2024 (KR) 10-2024-0026722

(51) Int. Cl. H01L 25/065; H01L 23/00

(52) U.S. Cl. CPC H01L 25/0657; H01L 24/32; H01L 24/48; H01L 2224/32145; H01L 2224/32225; H01L 2224/48147; H01L 2224/48227; H01L 2225/0651; H01L 2225/06524; H01L 2225/06562

(57) ABSTRACT

A semiconductor package includes a package substrate, a first semiconductor chip disposed on the package substrate, and a second semiconductor chip stacked in a step structure on the first semiconductor chip. A first chip pad is disposed on a first front surface of the first semiconductor chip, and the first chip pad is connected to a first upper surface connection pad disposed on the package substrate. A second chip pad is disposed on a second front surface of the second semiconductor chip, and the second chip pad is connected to a second upper surface connection pad disposed on the package substrate by a vertical wire.

### CROSS-REFERENCE TO RELATED APPLICATION

This application claims priority under 35 U.S.C. § 119 from Korean Patent Application No. 10-2024-0026722, filed on Feb. 23, 2024 in the Korean Intellectual Property office, the contents of which are herein incorporated by reference in their entirety.

### TECHNICAL FIELD

Embodiments of the inventive concept are directed to a semiconductor package, and more particularly, to a semiconductor package that includes a vertical wire.

### DISCUSSION OF THE RELATED ART

With the rapid development of the electronic industry and user demand, electronic devices have become more compact and lightweight, and accordingly, semiconductor devices, which are major components of electronic devices, are required to have high integration and large capacity. However, the high integration of such semiconductor devices has reached a limit. Accordingly, a semiconductor package that includes a plurality of semiconductor chips is being developed to achieve a large capacity. As the demand for high capacity semiconductor devices increases, a stacked semiconductor package, in which a plurality of semiconductor chips in the semiconductor package are stacked, is being developed.

The stacked semiconductor package includes semiconductor chips stacked in a vertical direction on a package substrate. An electrical input/output between a plurality of stacked semiconductor chips and the package substrate is provided by using wire bonding. Due to the wire bonding of a plurality of stacked semiconductor chips, the semiconductor package may become thick and a manufacturing process thereof may become more complicated.

### SUMMARY

Embodiments of the inventive concept provide a semiconductor package in which a manufacturing process thereof is simplified and reliability and productivity thereof are increased while a thickness thereof is reduced.

According to an embodiment of the inventive concept, there is provided a semiconductor package that includes a package substrate, a first semiconductor chip disposed on the package substrate, and a second semiconductor chip stacked in a step structure on the first semiconductor chip. A first back surface of the first semiconductor chip faces the package substrate, the first back surface is opposite to a first front surface of the first semiconductor chip, and the first front surface of the first semiconductor chip includes a first active surface of the first semiconductor chip. A second front surface of the second semiconductor chip faces the first front surface and includes a second active surface of the second semiconductor chip. A first chip pad is disposed on the first front surface of the first semiconductor chip, and the first chip pad is connected to a first upper surface connection pad disposed on the package substrate. A second chip pad is disposed on the second front surface of the second semiconductor chip, and the second chip pad is connected to a second upper surface connection pad disposed on the package substrate by a vertical wire.

According to another embodiment of the inventive concept, there is provided a semiconductor package that includes a package substrate and a plurality of semiconductor chips stacked in a step structure on the package substrate. A front surface of each of the semiconductor chips faces the package substrate, and the front surface of each semiconductor chip includes an active surface of each semiconductor chip. Each of the plurality of semiconductor chips includes a chip pad disposed on the front surface of the semiconductor chip. The package substrate includes an upper surface connection pad disposed on an upper surface of the package substrate that faces the front surface of the semiconductor chip. Each chip pad is individually connected to a corresponding upper surface connection pad by a vertical wire, and a wire ball is integrally formed with the vertical wire at one end of the vertical wire, another end of the vertical wire faces the chip pad, and a chip connection member is disposed at the another end of the vertical wire. The chip connection member connects the another end of the vertical wire to the chip connection member, and the upper surface connection pad that corresponds to the chip pad is disposed directly under the chip pad.

According to another embodiment of the inventive concept, there is provided a semiconductor package that includes a package substrate, a first semiconductor chip disposed on the package substrate, and a second semiconductor chip stacked in a step structure on the first semiconductor chip. A first back surface of the first semiconductor chip faces the package substrate and is opposite to a first front surface of the first semiconductor chip. The first front surface includes of the first semiconductor chip includes a first active surface of the first semiconductor chip. A second front surface of the second semiconductor chip faces the first front surface of the first semiconductor chip, and the second front surface of the second semiconductor chip includes a second active surface of the second semiconductor chip. A first chip pad is disposed on the first front surface of the first semiconductor chip, and the first chip pad is connected to a first upper surface connection pad disposed on the package substrate by a first bonding wire. A second chip pad is disposed on the second front surface of the second semiconductor chip, and the second chip pad is connected to a second upper surface connection pad disposed on the package substrate by a vertical wire. The vertical wire includes a wire ball, the wire ball is integrally formed with the vertical wire at one end of the vertical wire, and the wire ball is in contact with the second upper surface connection pad. A horizontal width of the wire ball is greater than a horizontal width of the vertical wire. A chip connection member is disposed at another end of the vertical wire, and the chip connection member is disposed between the second chip pad and the vertical wire to connect the second chip pad to the vertical wire. A first adhesive film is disposed on the first back surface of the first semiconductor chip, a second adhesive film is disposed on the second front surface of the second semiconductor chip, and at least a portion of a side surface of the chip connection member is surrounded by the second adhesive film. A horizontal width of the chip connection member decreases away from the second chip pad. A first height that is a maximum height of the first bonding wire from the package substrate is lower than a second height that is a height of a second back surface of the second semiconductor chip from the package substrate, and the second back surface is opposite to the second front surface of the second semiconductor chip.

### BRIEF DESCRIPTION OF THE DRAWINGS

FIG. 1 is a cross-sectional view of a semiconductor package according to an embodiment.

FIGS. 2A through 2C are cross-sectional views of enlarged portion A of a semiconductor package, according to embodiments.

FIG. 3 is a cross-sectional view of a semiconductor package according to an embodiment.

FIGS. 4A through 4C are cross-sectional views of enlarged portion A of a semiconductor package, according to embodiments.

FIG. 5 illustrates a semiconductor package according to an embodiment.

FIG. 6 is a cross-sectional view of a semiconductor package according to an embodiment.

FIGS. 7A through 7F are cross-sectional views that sequentially illustrate a process of manufacturing a semiconductor package, according to an embodiment.

FIGS. 8A through 8C are cross-sectional views that sequentially illustrate a process of manufacturing a semiconductor package, according to embodiments.

### DETAILED DESCRIPTION OF THE EMBODIMENTS

Hereinafter, embodiments of the inventive concept are described in detail with reference to the accompanying drawings.

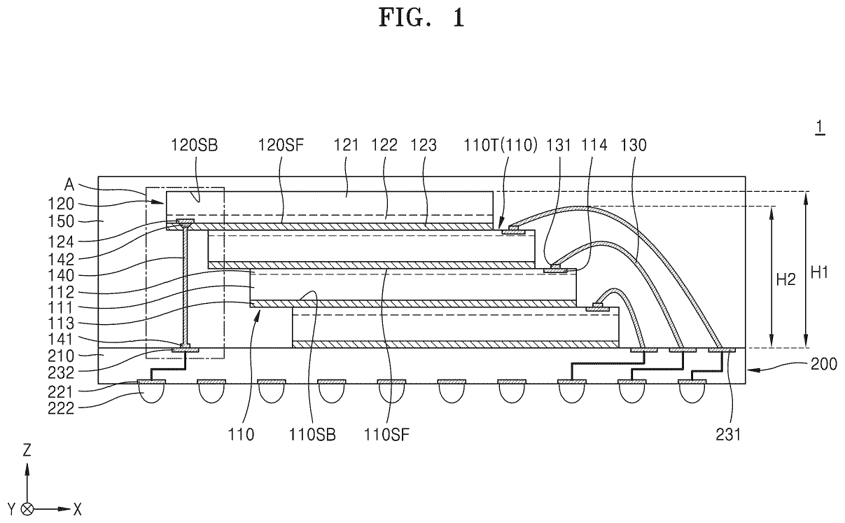

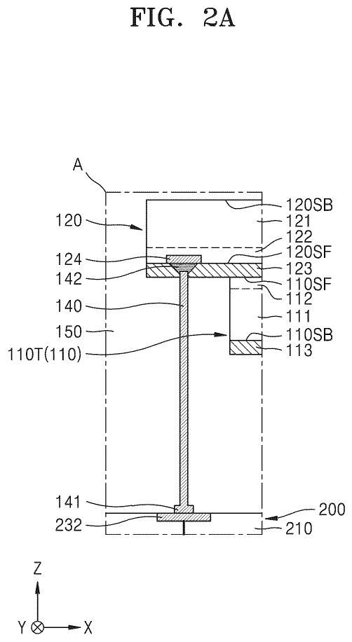

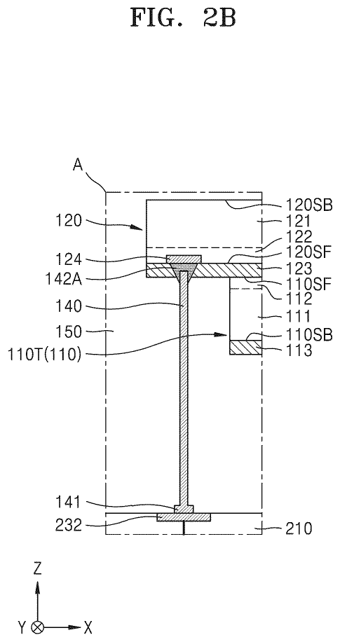

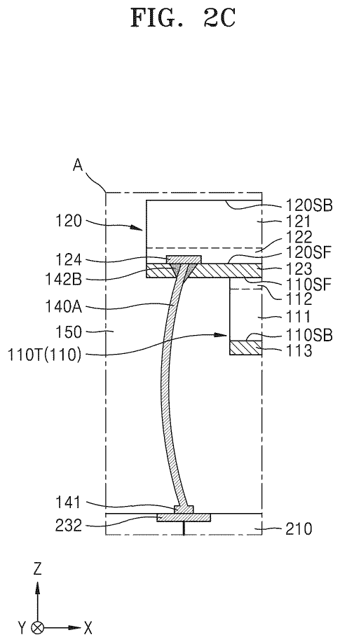

FIG. 1 is a cross-sectional view of a semiconductor package 1 according to an embodiment. FIGS. 2A through 2C are cross-sectional views of enlarged portion A of the semiconductor package 1, according to embodiments.

Referring to FIGS. 1 and 2A, in an embodiment, the semiconductor package 1 includes a package substrate 200, a first semiconductor chip 110 disposed on the package substrate 200, and a second semiconductor chip 120 stacked on the first semiconductor chip 110. In addition, the semiconductor package 1 includes a first bonding wire 130 that electrically connects the first semiconductor chip 110 to the package substrate 200, and a vertical wire 140 that electrically connects the second semiconductor chip 120 to the package substrate 200.

The package substrate 200 includes a base layer 210, a first upper surface connection pad 231 and a second upper surface connection pad 232 disposed on an upper surface of the package substrate 200, and a plurality of external connection pads 221 disposed on a lower surface of the package substrate 200. In some embodiments, the base layer 210 includes a plurality of stacked sub-base layers.

The first upper surface connection pad 231 and the second upper surface connection pad 232 are disposed on the upper surface of the package substrate 200. A plurality of first upper surface connection pads 231 and a plurality of the second upper surface connection pads 232 are provided. The plurality of external connection pads 221 are disposed on the lower surface of the package substrate 200. For example, the first upper surface connection pad 231 and the second upper surface connection pad 232 are disposed on an upper surface of the base layer 210, and the plurality of external connection pads 221 are disposed under a lower surface of the base layer 210.

In some embodiments, the first upper surface connection pad 231, the second upper surface connection pad 232, and the plurality of external connection pads 221 protrude from the base layer 210. For example, the first upper surface connection pad 231 and the second upper surface connection pad 232 protrude upward from the upper surface of the base layer 210, and the plurality of external connection pads 221 protrude downward from the lower surface of the base layer 210.

In some other embodiments, the first upper surface connection pad 231, the second upper surface connection pad 232, and the plurality of external connection pads 221 are buried in the base layer 210, and then, upper surfaces of the first upper surface connection pad 231 and the second upper surface connection pad 232 are coplanar with the upper surface of the base layer 210, and lower surfaces of the plurality of external connection pads 221 are coplanar with the lower surface of the base layer 210.

The first upper surface connection pad 231 and the second upper surface connection pad 232 are electrically connected to the plurality of external connection pads 221 by wiring formed in the base layer 210. The first upper surface connection pad 231 and the second upper surface connection pad 232 are connected to the first semiconductor chip 110 and the second semiconductor chip 120, respectively, and the first semiconductor chip 110 and the second semiconductor chip 120 are electrically connected to the plurality of external connection pads 221 so that signal exchange with an external electronic device is possible. A plurality of external connection terminals 222 are respectively disposed on the plurality of external connection pads 221. For example, a plurality of external connection terminals 220 includes solder balls or solder paste. The wiring formed in the base layer 210 is illustrated in a simplified manner.

A solder resist layer covers the upper surface and the lower surface of the base layer 210. The solder resist layer includes an upper surface solder resist layer that covers the upper surface of the base layer 210 and a lower surface solder resist layer that covers the lower surface of the base layer 210. At least a portion of each of the first upper surface connection pad 231 and the second upper surface connection pad 232 are exposed without being covered by the upper surface solder resist layer. At least a portion of each of the plurality of external connection pads 221 are exposed without being covered by the solder resist layer.

In some embodiments, the package substrate 200 does not include at least one of the upper surface solder resist layer or the lower surface solder resist layer. For example, the package substrate 200 includes the lower surface solder resist layer, but not the upper surface solder resist layer.

In some embodiments, the base layer 210 includes at least one of phenol resin, epoxy resin, or polyimide. For example, the base layer 210 includes at least one of flame retardant 4 (FR4), tetrafunctional epoxy, polyphenylene ether, epoxy/polyphenylene oxide, bismaleimide triazine (BT), thermount, cyanate ester, polyimide, or liquid crystal polymer.

The first semiconductor chip 110 is disposed on the package substrate 200. In some embodiments, a plurality of the first semiconductor chips 110 are disposed on the package substrate 200. The plurality of first semiconductor chips 110 are sequentially stacked on the package substrate 200 in a vertical direction (Z direction). Each of the plurality of first semiconductor chips 110 is offset in the horizontal direction and the plurality of first semiconductor chips 110 form a step shape.

In an embodiment, each of the plurality of first semiconductor chips 110 is offset in the first horizontal direction (X-axis direction) with respect to the lowermost first semiconductor chip 110 and is stacked in a step shape. In an embodiment, each of the plurality of first semiconductor chips 110 is offset in a diagonal direction with respect to the lowermost first semiconductor chip 110 and is stacked in a step shape. The diagonal direction includes both a first horizontal direction (X-axis direction) component and a second horizontal direction (Y direction) component.

The uppermost first semiconductor chip 110 of the plurality of stacked first semiconductor chips 110 may be referred to as an uppermost first semiconductor chip 110T.

The first semiconductor chip 110 includes a first semiconductor substrate 111. In an embodiment, the first semiconductor substrate 111 includes silicon (Si). In other embodiments, the first semiconductor substrate 111 includes a semiconductor element such as germanium (Ge), or a compound semiconductor such as at least one of silicon carbide (SiC), gallium arsenide (GaAs), indium arsenide (InAs), or indium phosphide (InP). In other embodiments, the first semiconductor substrate 111 has a silicon on insulator (SOI) structure. For example, the first semiconductor substrate 111 includes a buried oxide (BOX) layer. The first semiconductor substrate 111 includes a conductive region, such as a well doped with impurities. The first semiconductor substrate 111 may have various device separation structures such as a shallow trench isolation (STI) structure. The first semiconductor substrate 111 includes a first active surface 112 and a first inactive surface opposite to the first active surface 112.

A semiconductor device that includes various types of individual devices can be formed on the first active surface 112 of the first semiconductor chip 110. The plurality of individual devices include various microelectronic devices, such as a metal-oxide-semiconductor field effect transistor (MOSFET), a complementary metal-insulator-semiconductor (CMOS) transistor, an image sensor such as a system large scale integration (LSI) and CMOS imaging sensor (CIS), a micro-electro-mechanical system (MEMS), an active device, a passive device, etc.

The plurality of individual devices are electrically connected to the conductive area of the first semiconductor substrate 111. In addition, each of the plurality of individual devices is electrically separated from an adjacent individual device by an insulating layer.

For example, the first semiconductor chip 110 includes a memory semiconductor chip. In some embodiments, the memory semiconductor chip includes, for example, a non-volatile memory device, such as at least one of a flash memory, a phase change random access memory (RAM) (PRAM), a magnetic RAM (MRAM), a ferroelectric RAM (FeRAM), or a resistive RAM (RRAM). The flash memory includes, for example, a V-NAND flash memory. In some embodiments, the memory semiconductor chip includes a volatile memory device, such as a dynamic RAM (DRAM) or a static RAM (SRAM).

The first semiconductor chip 110 includes a first front surface 110SF and a first back surface 110SB. A surface of the first semiconductor chip 110 adjacent to the first active surface 112 may be referred to as the first front surface 110SF, and a surface opposite to the first front surface 110SF may be referred to as the first back surface 110SB. In embodiments of the inventive concept, a surface that faces upward with respect to the vertical direction may be referred to as an upper surface, and a surface that faces downward with respect to the vertical direction may be referred to as a lower surface. For example, the upper surface of the first semiconductor chip 110 includes the first front surface 110SF, and the lower surface of the first semiconductor chip 110 includes the first back surface 110SB. Accordingly, the first semiconductor chip 110 is arranged on the package substrate 200 so that the first active surface 112 of the first semiconductor chip 110 is farther from the package substrate 200 than the first inactive surface.

Each of the plurality of first semiconductor chips 110 includes a plurality of first chip pads 114 disposed on the upper surface of each of the plurality of first semiconductor chips 110. For example, the plurality of first chip pads 114 are disposed on the first active surface 112 of each of the plurality of first semiconductor chips 110. Each of the plurality of first semiconductor chips 110 is stacked on the package substrate 200 such that the first active surface 112 faces an upper side, such as a direction away from the package substrate 200. Each of the plurality of first semiconductor chips 110 is stacked on the package substrate 200 so that the first inactive surface faces downward, that is, toward the package substrate 200.

The plurality of first semiconductor chips 110 include a plurality of first adhesive films 113 that are attached to the lower surface of each of the plurality of first semiconductor chips 110, between each of the plurality of first semiconductor chips 110, and on a structure under the plurality of first semiconductor chips 110. For example, the first adhesive film 113 is disposed between the lowermost first semiconductor chip 110 and the package substrate 200, and the first adhesive film 113 is disposed on the package substrate 200. The first adhesive film 113 between each pair of adjacent first semiconductor chips 110, and the first adhesive film 113 is attached under each of the first semiconductor chips 110.

The first adhesive film 113 includes, for example, an inorganic adhesive or a polymer adhesive. The polymer adhesive includes, for example, a thermosetting polymer or a thermoplastic polymer. For a thermosetting resin, after a monomer is heat-molded, the thermosetting resin has a three-dimensional cross-link structure, and might not soften even when reheated. On the contrary, a thermoplastic resin includes a resin that exhibits thermoplastic characteristics when heated, and may have a linear polymer structure. In addition, the polymer adhesive can form as a hybrid type by mixing these two components.

The first chip pad 114 is connected to the first bonding wire 130. A wire ball 131 is integrally formed at one end of the first bonding wire 130 is attached to the first chip pad 114 so that the first bonding wire 130 is fixed on the first chip pad 114. The wire ball 131 has a shape generated during a wire bonding process, and is generated by deforming a portion of the bonding wire.

In some embodiments, the first chip pad 114 is connected to one end of the first bonding wire 130, and the other end of the first bonding wire 130 is connected to the first upper surface connection pad 231 of the package substrate 200. In an embodiment, each of the first chip pads 114 disposed in the plurality of first semiconductor chips 110 is connected to a corresponding first upper surface connection pad 231 by the first bonding wire 130. In an embodiment, the first bonding wire 130 connects between the first chip pads 114 respectively disposed in the plurality of first semiconductor chips 110. For example, the first bonding wire 130 connects the first chip pad 114 to the first upper surface connection pad 231, or the first bonding wire 130 connects between the first chip pad 114 and another first chip pad 114.

The second semiconductor chip 120 is disposed on the uppermost first semiconductor chip 110T of the plurality of first semiconductor chips 110. The second semiconductor chip 120 is stacked on the uppermost first semiconductor chip 110T in the vertical direction (Z direction). The second semiconductor chip 120 is offset from the uppermost first semiconductor chip 110T in the horizontal direction. Accordingly, the second semiconductor chip 120 and the plurality of first semiconductor chips 110 form a step structure when stacked on the package substrate 200.

In an embodiment, each first semiconductor chip 110 is offset in the first horizontal direction (X-axis direction) with respect to a lower first semiconductor chip 110 and form a step structure. In an embodiment, each first semiconductor chip 110 is offset a diagonal direction with respect to a lower first semiconductor chip 110 at the lowermost end in and form a step shape. The diagonal direction includes both the first horizontal direction (X-axis direction) component and the second horizontal direction (Y direction) component.

The second semiconductor chip 120 includes a second semiconductor substrate 121. The second semiconductor substrate 121 includes, for example, Si. The content of the second semiconductor substrate 121 is substantially similar to the content of the first semiconductor substrate 111. The second semiconductor substrate 121 has a second active surface 122 and a second inactive surface opposite to the second active surface 122.

A semiconductor device that includes various types of individual devices can be formed on the second active surface 122 of the second semiconductor chip 120. In addition, in an embodiment, the second semiconductor chip 120 includes a memory semiconductor chip.

The second semiconductor chip 120 includes a second front surface 120SF and a second back surface 120SB. A surface of the second semiconductor chip 120 adjacent to the second active surface 122 may be referred to as the second front surface 120SF, and a surface opposite to the second front surface 120SF may be referred to as the second back surface 120SB. An upper surface of the second semiconductor chip 120 is the second back surface 120SB, and a lower surface of the second semiconductor chip 120 is the second front surface 120SF. Accordingly, the second semiconductor chip 120 is arranged so that the second active surface 122 is closer to the package substrate 200 than the second inactive surface.

The second semiconductor chip 120 includes a second chip pad 124 disposed on the second front surface 120SF. For example, the second chip pad 124 is disposed on the second active surface 122 of the second semiconductor chip 120. The plurality of first semiconductor chips 110 and the second semiconductor chips 120 are arranged so that the first active surfaces 112 of the plurality of first semiconductor chips 110 and the second active surface 122 of the second semiconductor chip 120 face each other. For example, the plurality of first semiconductor chips 110 and the second semiconductor chips 120 are arranged so that the first front surfaces 110SF of the plurality of first semiconductor chips 110 and the second front surface 120SF of the second semiconductor chip 120 face each other.

A second adhesive film 123 is attached to the lower surface of the second semiconductor chip 120 and an upper surface of the first semiconductor chip 110 disposed under the second semiconductor chip 120, and is arranged between the second semiconductor chip 120 and the underlying first semiconductor chip 110. For example, the second adhesive film 123 is arranged between the uppermost first semiconductor chip 110T and the second semiconductor chip 120, and the second adhesive film 123 may be attached to the uppermost first semiconductor chip 110T.

The second adhesive film 123 includes, for example, an inorganic adhesive or a polymer adhesive. The content of the second adhesive film 123 is substantially the same as the content of the first adhesive film 113.

The vertical wire 140 connects between the second chip pad 124 and the second upper surface connection pad 232. A wire ball 141 is integrally formed at one end of the vertical wire 140 and is attached to the second upper surface connection pad 232, so that the vertical wire 140 is fixed on the second upper surface connection pad 232. A horizontal width of the wire ball 141 is greater than a thickness of the vertical wire 140. For example, the horizontal width of the wire ball 141 is greater than a horizontal width of the vertical wire 140, and is 1.5 times the thickness of the vertical wire 140.

Referring to FIG. 2A together, in an embodiment, the second chip pad 124 is connected to the vertical wire 140. A chip connection member 142 is disposed between the second chip pad 124 and the vertical wire 140. The second chip pad 124 is fixed to the vertical wire 140 by the chip connection member 142. The length of the vertical wire 140 is less than a distance between the second front surface 120SF and the upper surface of the package substrate 200. Accordingly, one end of the vertical wire 140 close to the second chip pad 124 is not in direct contact with the second chip pad 124.

At least a portion of the side surfaces of the chip connection member 142 is surrounded by the second adhesive film 123. In a process of attaching the chip connection member 142 to the vertical wire 140, the chip connection member 142 has a shape that extends along the side surface of the vertical wire 140 due to wetting of the vertical wire 140. The chip connection member 142 is disposed inside the second adhesive film 123.

For example, the chip connection member 142 extends along the side of the vertical wire 140, and has a shape in which a horizontal width decreases away from the second chip pad 124. A shape of the chip connection member 142 can vary depending on viscosity, an adhesion force between the vertical wire 140 and the chip connection member 142, and an adhesion force between the second adhesive film 123 and the chip connection member 142, in an attachment process of the chip connection member 142. The chip connection member 142 include, for example, a solder ball or a solder bump.

An encapsulating member 150 surrounds the plurality of first semiconductor chips 110, the second semiconductor chip 120, the first bonding wire 130, and the vertical wire 140, and is disposed on the package substrate 200. A side surface of the encapsulating member 150 is aligned with a side surface of the package substrate 200, and a planar shape of the encapsulating member 150 is the same as a planar shape of the package substrate 200. An upper surface of the encapsulating member 150 is coplanar with or higher than the second back surface 120SB of the second semiconductor chip 120. For example, as illustrated in FIG. 1, the upper surface of the encapsulating member 150 is higher than the second back surface 120SB of the second semiconductor chip 120, and covers the second back surface 120SB. The encapsulating member 150 includes, for example, an epoxy molding compound (EMC) or a polymer material.

Referring to FIG. 2B, in an embodiment, the length of the vertical wire 140 is less than a distance between the second front surface 120SF and the upper surface of the package substrate 200. Accordingly, one end of the vertical wire 140 close to the second chip pad 124 is not in direct contact with the second chip pad 124.

A portion of a side surface of a chip connection member 142A is surrounded by the second adhesive film 123. In the process of attaching the chip connection member 142A to the vertical wire 140, the chip connection member 142A extends along the side surface of the vertical wire 140 due to the wetting of the vertical wire 140. The chip connection member 142A extends along the vertical wire 140, and protrudes downward from the lower surface of the second adhesive film 123. Accordingly, the chip connection member 142A penetrates through the second adhesive film 123 and into the encapsulating member 150. For example, the horizontal width of the chip connection member 142A generally decreases away from the second chip pad 124.

Referring to FIG. 2C, in an embodiment, the length of a vertical wire 140A is greater than a vertical distance between the second front surface 120SF and the upper surface of the package substrate 200. Accordingly, one end of the vertical wire 140A close to the second chip pad 124 is in direct contact with the second chip pad 124. In addition, the vertical wire 140A has a curved shape. A middle portion of the vertical wire 140A is laterally curved outward, and accordingly, the vertical wire 140A has an entirely curved shape. For example, the middle portion of the vertical wire 140A is laterally offset.

A difference between a shape of the vertical wire 140 in FIGS. 2A and 2B and a shape of the vertical wire 140A in FIG. 2C is generated due to a length error of the vertical wire 140A, which can occur in the process of forming the vertical wire 140A, due to a difference in vertical levels in the process of stacking the plurality of first semiconductor chips 110 and the second semiconductor chip 120.

At least a portion of a side surface of a chip connection member 142B is surrounded by the second adhesive film 123. The chip connection member 142B extends along the side surface of the vertical wire 140A.

In some embodiments, the chip connection member 142B extends along the vertical wire 140A, and protrudes downward from the lower surface of the second adhesive film 123 and into the encapsulating member 150. Accordingly, the chip connection member 142A penetrates the second adhesive film 123. For example, the horizontal width of the chip connection member 142A generally decreases away from the second chip pad 124. In other embodiments, while the chip connection member 142B extends along the vertical wire 140A, the chip connection member 142B is provided inside the second adhesive film 123. For example, the chip connection member 142B does not protrude from the lower surface of the second adhesive film 123 into the encapsulating member 150.

A plurality of vertical wires 140 and chip connection members 142 that are provided in the semiconductor package 1, according to an embodiment illustrated in FIG. 1, have one of the forms disclosed in FIGS. 2A through 2C, and forms of the plurality of vertical wires 140 and forms of the chip connection member 142 that are provided in the semiconductor package 1 may be the same as or different from each other.

A vertical level of the highest point of the plurality of first semiconductor chips 110 and the second semiconductor chip 120 from the package substrate 200 may be referred to as a first height H1. A vertical level of the highest point of the first bonding wire 130 from the package substrate 200 may be referred to as a second height H2. The second height H2 is equal to or lower than the first height H1.

For example, as illustrated in FIG. 1, because the second back surface 120SB of the second semiconductor chip 120 is the highest vertical point from the package substrate 200, a vertical distance from the package substrate 200 to the upper surface of the second semiconductor chip 120 corresponds to the first height H1. A highest point of the plurality of first bonding wires 130 that are respectively connected to the plurality of first semiconductor chips 110 from the package substrate 200 is a portion of the first bonding wire 130 connected to the uppermost first chip pad 114. The second height H2 is lower than the first height H1.

In the semiconductor package 1 according to an embodiment, the plurality of first semiconductor chips 110 are stacked, and the second semiconductor chip 120 is disposed on the uppermost first semiconductor chip 110T and is the uppermost end of the stacked semiconductor chips. While the plurality of first semiconductor chips 110 are connected to the package substrate 200 via the first bonding wires 130 connected to the first chip pads 114 disposed on the upper surfaces of the plurality of first semiconductor chips 110, the second semiconductor chip 120 is connected to the package substrate 200 by the vertical wire 140 connected to the second chip pad 124 disposed on the lower surface of the second semiconductor chip 120. Accordingly, because a bonding wire is not connected to the upper surface of the second semiconductor chip 120, but the vertical wire 140 is connected to the lower surface of the second semiconductor chip 120, the bonding wires 130 do not protrude higher than the upper surface of the second semiconductor chip 120. Accordingly, the vertical thickness of the semiconductor package 1 according to an embodiment of the inventive concept can be reduced.

The semiconductor package 1 according to an embodiment of the inventive concept can be manufactured by subsequent processes on the package substrate 200, which has been manufactured in advance, such as the manufacturing processes of the semiconductor package 1 to be described below. For example, because the semiconductor package I can be manufactured by stacking a plurality of semiconductor chips (110 and 120) on the previously manufactured package substrate 200, the productivity of the semiconductor package 1 can be increased. In addition, because a printed circuit board can be adopted as the package substrate 200, the manufacturing cost of the semiconductor package 1 can be reduced.

In addition, the chip connection member 142 is provided between the vertical wire 140 and the second chip pad 124 of the second semiconductor chip 120, and a reliable connection between the vertical wire 140 and the second chip pad 124 can be obtained. Thus, the reliability of the semiconductor package 1 can be increased.

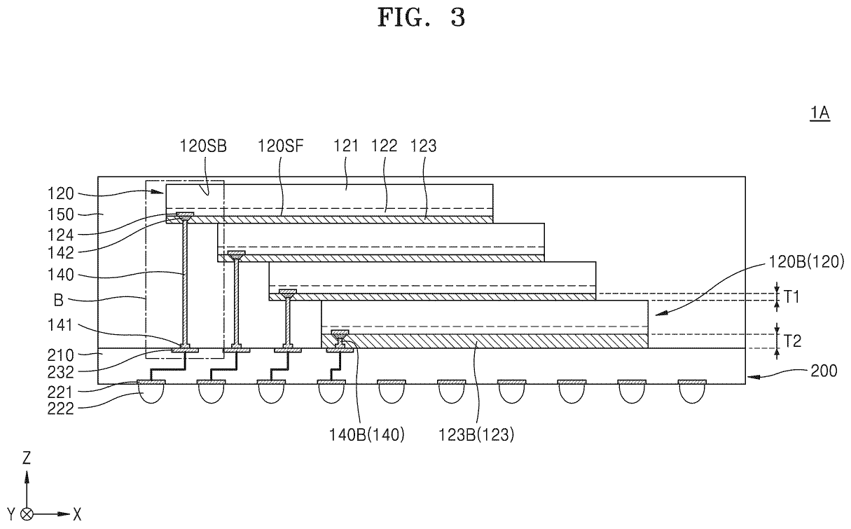

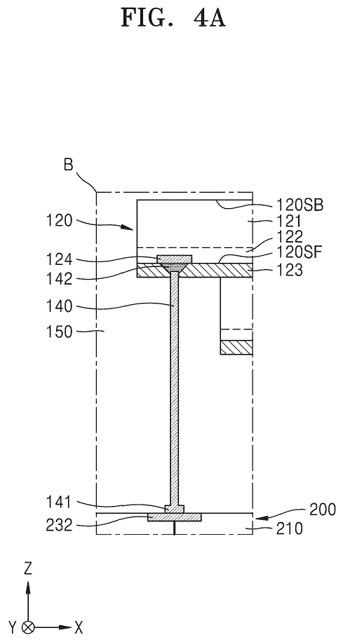

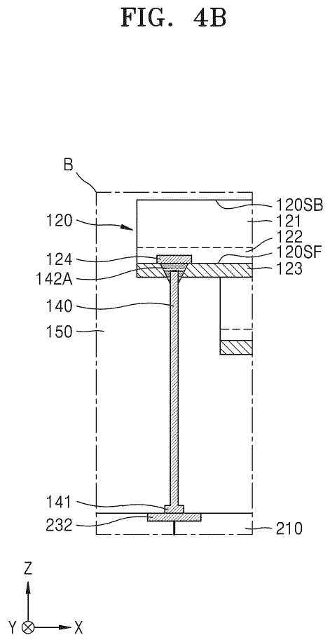

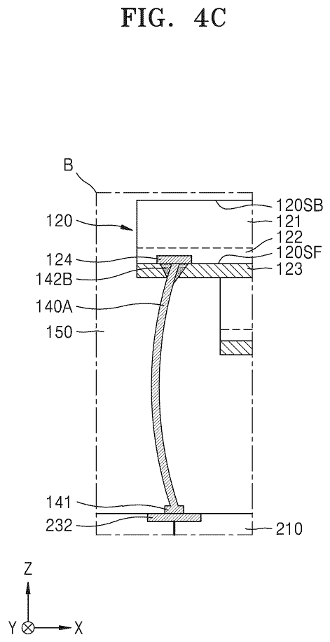

FIG. 3 is a cross-sectional view of a semiconductor package 1A according to an embodiment. FIGS. 4A through 4C are cross-sectional views of enlarged portion A of the semiconductor package 1A, according to embodiments.

Referring to FIGS. 3 and 4A, in an embodiment, the semiconductor package 1A includes a plurality of stacked second semiconductor chips 120, the package substrate 200 on which the plurality of second semiconductor chips 120 are disposed, and the vertical wire 140.

The package substrate 200 includes the base layer 210 and the second upper surface connection pad 232 disposed on the upper surface of the package substrate 200, and the plurality of external connection pads 221 disposed on the lower surface of the package substrate 200. In some embodiments, the base layer 210 includes a plurality of stacked sub-base layers.

The second upper surface connection pad 232 are disposed on the upper surface of the package substrate 200. The second upper surface connection pad 232 is connected to the second chip pad 124 corresponding thereto by the vertical wire 140. For example, as illustrated in FIG. 3, below the second chip pads 124 on the lower surfaces of the plurality of second semiconductor chips 120, the corresponding second upper surface connection pads 232 are directly arranged. For example, the second upper surface connection pads 232 that respectively correspond to the second chip pads 124 overlap at least a portion of the second chip pad 124 in the vertical direction.

The second semiconductor chip 120 is disposed on the package substrate 200. In some embodiments, a plurality of the second semiconductor chips 120 are disposed on the package substrate 200. The plurality of second semiconductor chips 120 are sequentially stacked on the package substrate 200 in the vertical direction (Z direction). The plurality of second semiconductor chips 120 are offset in the horizontal direction and form a step structure.

In an embodiment, each second semiconductor chip 120 is offset in the first horizontal direction (X-axis direction) with respect to a lower second semiconductor chip 120, and is stacked in a step structure. In an embodiment, each second semiconductor chip 120 is offset in a diagonal direction with respect to a lower second semiconductor chip 120, and is stacked in a step structure.

The second semiconductor chip 120 includes the second semiconductor substrate 121. The second semiconductor substrate 121 includes the second active surface 122 and the second inactive surface opposite to the second active surface 122. The second semiconductor chip 120 includes a second front surface 120SF and a second back surface 120SB. The plurality of second semiconductor chips 120 of the semiconductor package 1A are arranged so that the second active surface 122 is closer to the package substrate 200 than the second inactive surface. For example, the second front surface 120SF of each of the plurality of second semiconductor chips 120 faces the package substrate 200.

The second semiconductor chip 120 includes the second chip pad 124 disposed on the second front surface 120SF of the second semiconductor chip 120. For example, the second chip pad 124 is disposed on the second active surface 122 of the second semiconductor chip 120. The second semiconductor chip 120 is arranged such that the second active surface 122 is a lower side of the second semiconductor chip 120 and faces the package substrate 200. The second chip pad 124 faces the upper surface of the package substrate 200.

The second adhesive film 123 is attached to the lower surface of an upper second semiconductor chip 120 of a pair of adjacent second semiconductor chips 120 and the upper surface of a lower second semiconductor chip 120 of the pair of adjacent second semiconductor chips 120. The second adhesive film 123 is disposed between the second semiconductor chip 120 and the package substrate 200, and the second adhesive film 123 disposed between the second semiconductor chip 120 and the package substrate 200 may be referred to as a lowermost second adhesive film 123B. The second adhesive film 123 includes, for example, an inorganic adhesive or a polymer adhesive.

The vertical wire 140 connects the second chip pad 124 to the second upper surface connection pad 232. The wire ball 141 integrally formed at one end of the vertical wire 140 is attached to the second upper surface connection pad 232, and the vertical wire 140 is fixed on the second upper surface connection pad 232. The chip connection member 142 is provided between the second chip pad 124 and the vertical wire 140. The second chip pad 124 is connected to the vertical wire 140 via the chip connection member 142.

Referring to FIG. 4A, in an embodiment, the length of the vertical wire 140 is less than a distance between the second front surface 120SF and the upper surface of the package substrate 200. Accordingly, an end of the vertical wire 140 close to the second chip pad 124 is not in direct contact with the second chip pad 124.

At least a portion of the side surfaces of the chip connection member 142 is surrounded by the second adhesive film 123. In a process of attaching the chip connection member 142 to the vertical wire 140, the chip connection member 142 extends along the side surface of the vertical wire 140 due to wetting of the vertical wire 140. The chip connection member 142 is disposed inside the second adhesive film 123. For example, the chip connection member 142 extends along the side of the vertical wire 140, and the horizontal width of the chip connection member 142 generally decreases away from the second chip pad 124.

Referring to FIG. 4B, in an embodiment, the length of the vertical wire 140 is less than a distance between the second front surface 120SF and the upper surface of the package substrate 200. An end of the vertical wire 140 close to the second chip pad 124 is not in direct contact with the second chip pad 124. The chip connection member 142A extends along the vertical wire 140, and protrudes downward from the lower surface of the second adhesive film 123 and into the encapsulating member 150. Accordingly, the chip connection member 142A penetrates through the second adhesive film 123. For example, the horizontal width of the chip connection member 142A generally decreases away from the second chip pad 124.

Referring to FIG. 4C, in an embodiment, the length of the vertical wire 140 is greater than a distance between the second front surface 120SF and the upper surface of the package substrate 200. Accordingly, an end of the vertical wire 140 close to the second chip pad 124 is in direct contact with the second chip pad 124. In addition, the vertical wire 140 has a curved shape. A middle portion of the vertical wire 140A is laterally curved outward, and accordingly, the vertical wire 140A has an entirely curved shape.

The chip connection member 142B extends along the vertical wire 140A, and the horizontal width of the chip connection member 142A generally decreases away from the second chip pad 124.

In some embodiments, the chip connection member 142A protrudes downward from the lower surface of the second adhesive film 123 and into the encapsulating member 150. Accordingly, the chip connection member 142A penetrates through the second adhesive film 123. In other embodiments, while the chip connection member 142B extends along the vertical wire 140A, the chip connection member 142B is disposed inside the second adhesive film 123. For example, the chip connection member 142B does not protrude downward from the lower surface of the second adhesive film 123 and into the encapsulating member 150.

The plurality of vertical wires 140 and chip connection members 142 that are provided in the semiconductor package 1A according to an embodiment illustrated in FIG. 3 have one of the forms disclosed in FIGS. 4A through 4C, and the forms of the plurality of vertical wires 140 and the forms of the chip connection members 142 may all be the same as or different from each other.

The vertical thickness of the lowermost second adhesive film 123B disposed between a lowermost second semiconductor chip 120B and the package substrate 200 differs from the vertical thickness of the second adhesive film 123 disposed between a pair of adjacent second semiconductor chips 120. For example, a first vertical thickness T1 of the second adhesive film 123 disposed between two second semiconductor chips 120 is less than a second vertical thickness T2 of the lowermost second adhesive film 123B disposed between the lowermost second semiconductor chip 120B and the package substrate 200. For example, the first thickness T1 is about 15 μm to about 30 μm, and the second thickness T2 is about 35 μm to about 50 μm.

The lowermost second adhesive film 123B surrounds side surfaces of a lowermost vertical wire 140B disposed between the second chip pad 124 of the lowermost second semiconductor chip 120B and the corresponding second upper surface connection pad 232. A wire ball 141B provided at one end of the lowermost vertical wire 140B is also similarly surrounded. For example, because the lowermost vertical wire 140B needs to be provided, the second thickness T2 of the lowermost second adhesive film 123B is greater than the first thickness T1.

The encapsulating member 150 surrounds the plurality of second semiconductor chips 120 and the plurality of vertical wires 140, and is disposed on the package substrate 200. The side surface of the encapsulating member 150 is aligned with the side surface of the package substrate 200, and the planar shape of the encapsulating member 150 is the same as the planar shape of the package substrate 200. The upper surface of the encapsulating member 150 is coplanar with or higher than the second back surface 120SB, which is the upper surface of the second semiconductor chip 120.

In the semiconductor package 1A according to an embodiment of the inventive concept, the package substrate 200 is manufactured first, the subsequent processes manufacture the semiconductor package 1A, and the productivity of the semiconductor package 1 is increased. In addition, because a printed circuit board can be adopted as the package substrate 200, the manufacturing cost of the semiconductor package 1 can be reduced.

In addition, the chip connection member 142 is provided between the vertical wire 140 and the second chip pad 124 of the second semiconductor chip 120, and a reliable connection between the vertical wire 140 and the second chip pad 124 can be obtained. Thus, the reliability of the semiconductor package 1A can be increased.

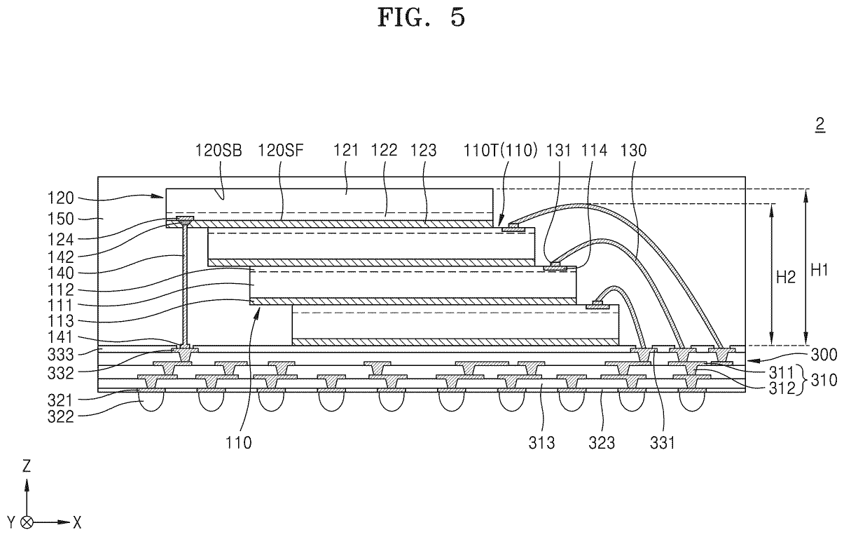

FIG. 5 illustrates a semiconductor package 2 according to an embodiment. Differences from the semiconductor package 1 of FIG. 1 are mainly described.

Referring to FIG. 5, in an embodiment, the semiconductor package 2 includes a rewiring substrate 300, the first semiconductor chip 110 disposed on the rewiring substrate 300, the second semiconductor chip 120 stacked on the first semiconductor chip 110, the first bonding wire 130, and the vertical wire 140 that electrically connects the second semiconductor chip 120 to the package substrate 200. The rewiring substrate 300 may be referred to as a package substrate.

The rewiring substrate 300 includes a plurality of rewiring insulating layers 313, a plurality of rewiring line patterns 311 disposed on at least one of an upper surface or a lower surface of each of the plurality of rewiring insulating layers 313, and a plurality of rewiring via patterns 312 respectively in contact with some of the plurality of rewiring line patterns 311. The plurality of rewiring line patterns 311 and the plurality of rewiring via patterns 312 may be collectively referred to as rewiring patterns 310.

Each of the plurality of rewiring insulating layers 313 includes, for example, a material layer that includes an organic compound. In some embodiments, each of a plurality of rewiring insulating layers 313 includes a material layer that includes an organic polymer material. In some embodiments, each of the plurality of rewiring insulating layers 313 includes a photosensitive polyimide (PSPI).

Each of the rewiring line pattern 311 and the rewiring via pattern 312 includes a metal, such as at least one of copper (Cu), tungsten (W), titanium (Ti), titanium tungsten (TiW), titanium nitride (TiN), tantalum (Ta), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), an alloy thereof, or a metal nitride thereof, but is not necessarily limited thereto.

Each of the rewiring line pattern 311 and the rewiring via pattern 312 includes a seed layer in contact with the rewiring insulating layer 313 and a conductive material layer on the seed layer. In some embodiments, the seed layer is formed by a physical vapor deposition process, and the conductive material layer is formed by an electroless plating process. A portion of the rewiring line pattern 311 is formed together with a portion of the rewiring via pattern 312 into one body. For example, the rewiring line pattern 311 is formed together with a portion of the rewiring via pattern 312 in contact with au upper side of the rewiring line pattern 311 or a portion of the rewiring via pattern 312 in contact with a lower side of the rewiring line pattern 311 into one body.

The rewiring line pattern 311 is interposed between two adjacent rewiring insulating layers 313, and the rewiring line pattern 311 are disposed on an upper surface of the uppermost rewiring insulating layer 313 and/or a lower surface of the lowermost rewiring insulating layer 313.

A plurality of external connection pads 321 are disposed on a lower surface of the rewiring substrate 300. A plurality of external connection terminals 322 are disposed on a lower surface of each of the plurality of external connection pads 321. The semiconductor package 2 may be connected to an external electronic device, such as a printed circuit board, etc., by the plurality of external connection terminals 322. A lower passivation layer 323 is disposed provided on the lower surface of the rewiring substrate 300.

A first upper surface connection pad 331 and a second upper surface connection pad 332 are disposed on the upper surface of the rewiring substrate 300. The first upper surface connection pad 331 and the second upper surface connection pad 332 are electrically connected to the rewiring pattern 310 of the rewiring substrate 300.

An upper passivation layer 333 is disposed on the upper surface of the rewiring substrate 300. The lower passivation layer 323 and the upper passivation layer 333 protect a semiconductor package from external physical and chemical damage, etc. The lower passivation layer 323 and the upper passivation layer 333 protect the rewiring substrate 300. The lower passivation layer 323 is located in a lower area of the rewiring substrate 300 to cover, for example, a lower surface of the rewiring insulating layer 313. The upper passivation layer 333 is located in an upper area of the rewiring substrate 300 to cover, for example, an upper surface of the rewiring insulating layer 313.

The lower passivation layer 323 and the upper passivation layer 333 include an insulating resin and an inorganic filler, but not glass fiber. For example, the lower passivation layer 323 and the upper passivation layer 333 include, but are not limited to, Ajinomoto build-up film (ABF), and may include a photo imageable dielectric (PID) or an insulating polymer, such as PSPI.

The lower passivation layer 323 and the upper passivation layer 333 include openings in the lower surface and the upper surface of the rewiring substrate 300, respectively. The first upper surface connection pad 331 and the second upper surface connection pad 332 are exposed through the opening of the upper passivation layer 333. The plurality of external connection pads 321 are exposed through the openings of the lower passivation layer 323.

The vertical wire 140 connects between the second chip pad 124 and the second upper surface connection pad 332. The wire ball 141 integrally formed at one end of the vertical wire 140 is attached to the second upper surface connection pad 232, so that the vertical wire 140 is fixed on the second upper surface connection pad 232.

The shapes of FIGS. 2A through 2C that illustrate portions of the semiconductor package 1 described above similarly apply to the semiconductor package 2 of FIG. 5.

In the semiconductor package 2 according to an embodiment of the inventive concept, the plurality of first semiconductor chips 110 are stacked, and the second semiconductor chip 120 is disposed on the uppermost first semiconductor chip 110T. The first bonding wire 130 does not protrude from the upper surface of the second semiconductor chip 120 at the uppermost end among the stacked semiconductor chips. Accordingly, the vertical thickness of the semiconductor package 2 according to an embodiment of the inventive concept can be reduced, and accordingly, a size of the semiconductor package 2 can be reduced.

The semiconductor package 2 according to an embodiment of the inventive concept can be manufactured by stacking the plurality of semiconductor chips 110 and the plurality of semiconductor chips 120 on a pre-manufactured rewiring substrate 300, so that the productivity of the semiconductor package 2 can be increased.

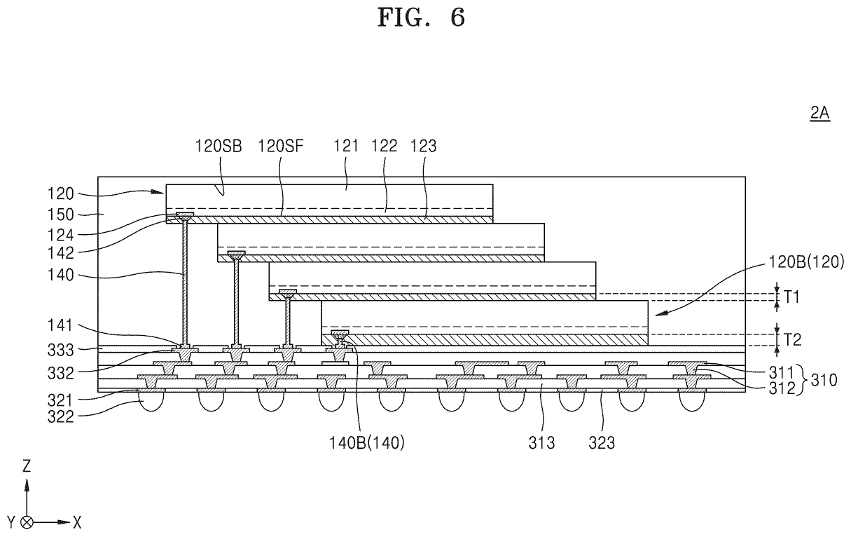

FIG. 6 is a cross-sectional view of a semiconductor package 2A according to an embodiment. Differences from the semiconductor package 1A of FIG. 3 are mainly described, and duplicate descriptions given above may be omitted.

Referring to FIG. 6, in an embodiment, the semiconductor package 1A includes the rewiring substrate 300, the plurality of second semiconductor chips 120 stacked on the rewiring substrate 300, and the plurality of vertical wires 140. The shapes of FIGS. 2A through 2C that illustrate portions of the semiconductor package 1A described above similarly apply to the semiconductor package 2A of FIG. 6.

The first thickness T1, which is the vertical thickness of the second adhesive film 123 interposed between the second semiconductor chip 120 on the second adhesive film 123 and the second semiconductor chip 120 under the second adhesive film 123, is less than the second thickness T2, which is the vertical thickness of the lowermost second adhesive film 123B arranged between the lowermost second semiconductor chip 120B and the package substrate 200. For example, the first thickness T1 is about 15 μm to about 30 μm, and the second thickness T2 is about 35 μm to about 50 μm.

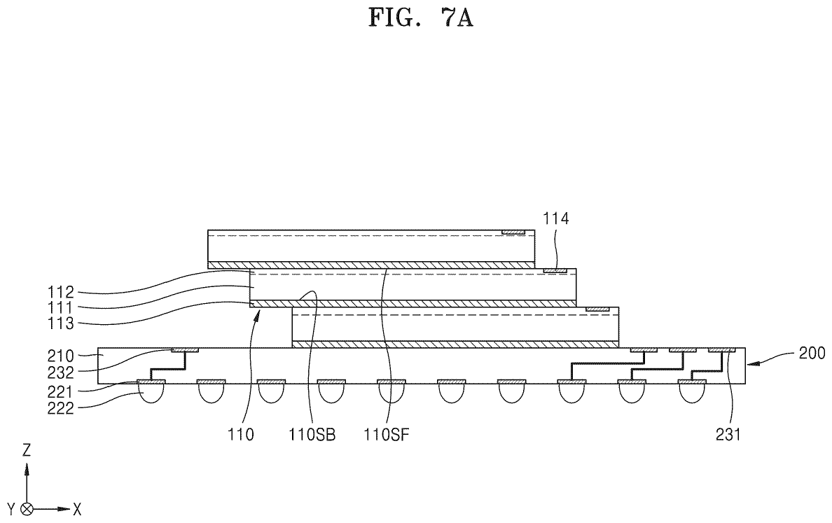

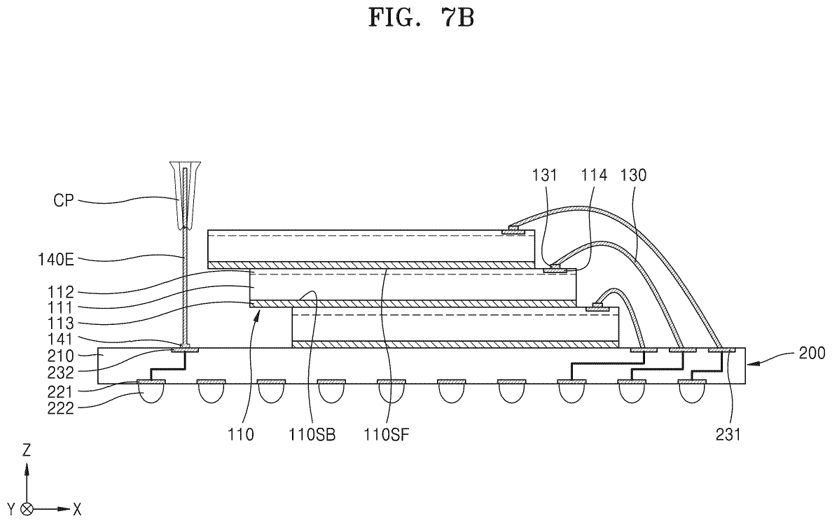

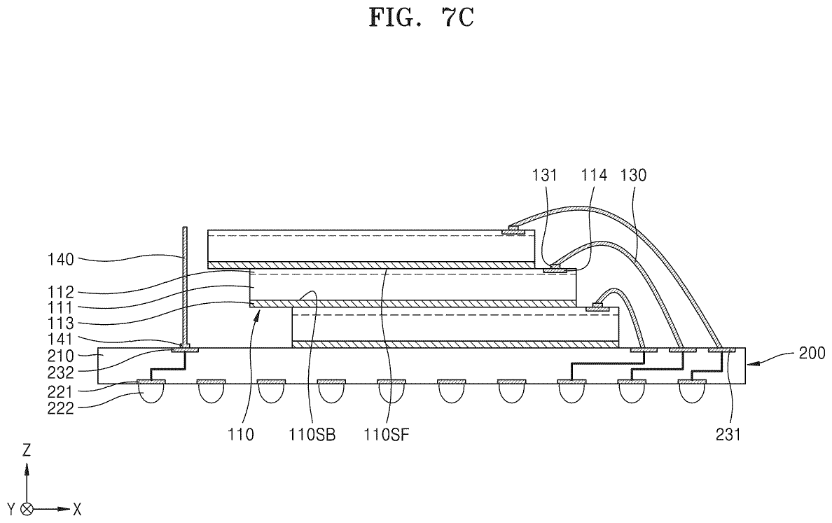

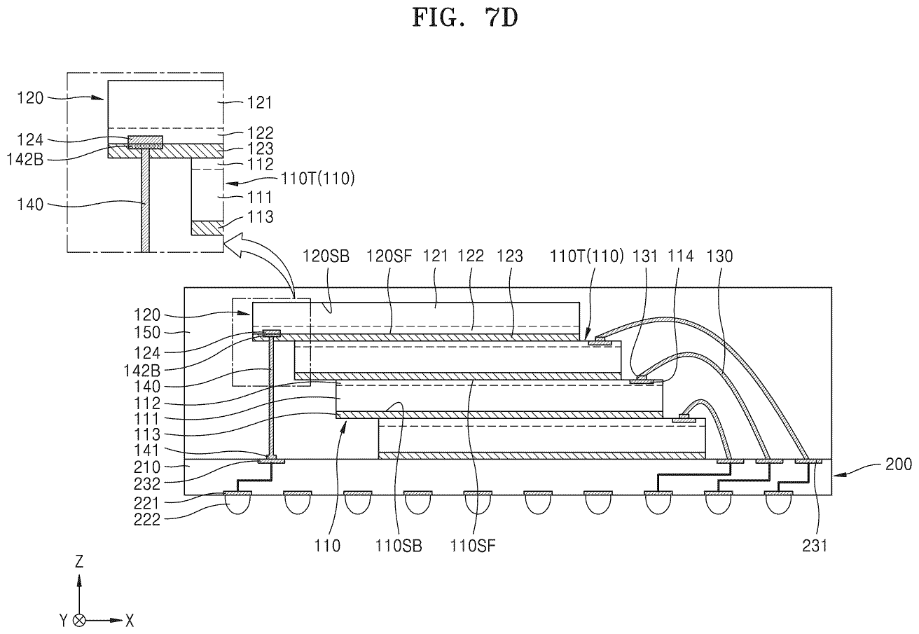

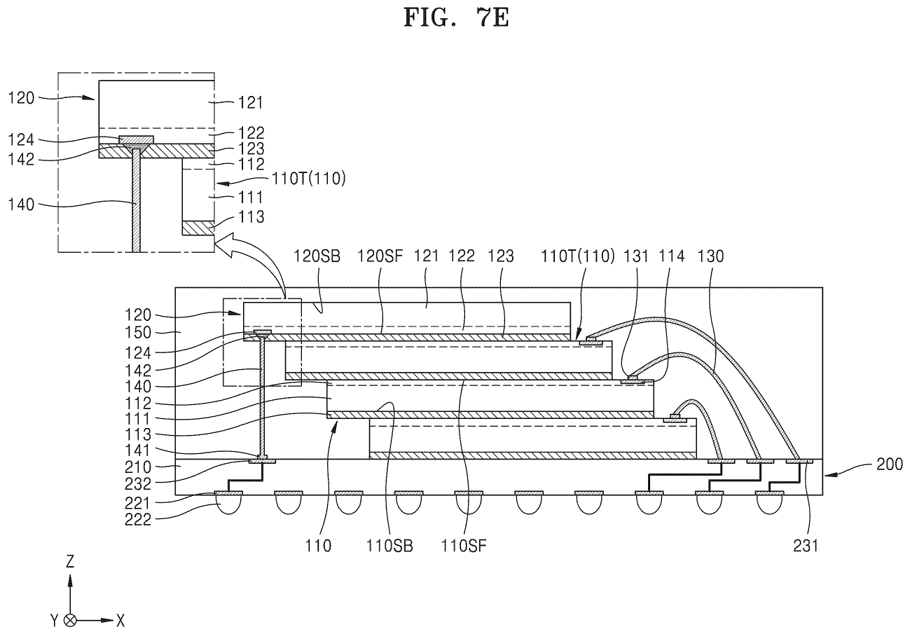

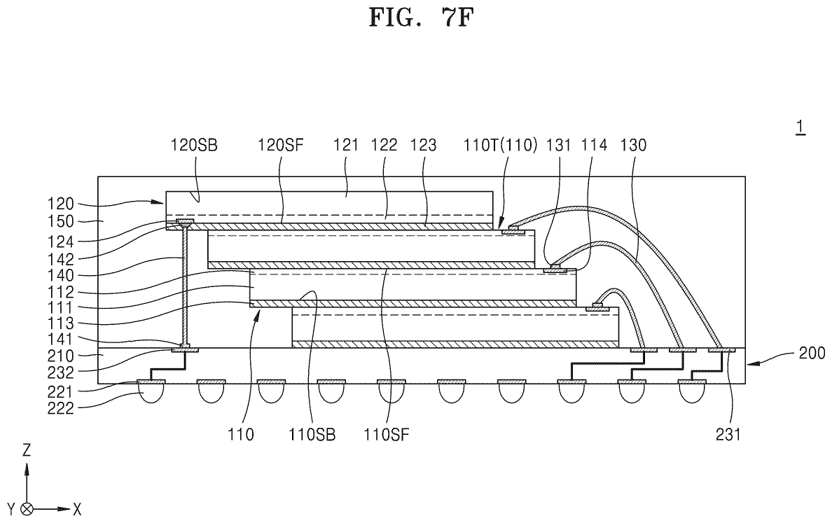

FIGS. 7A through 7F are cross-sectional views that sequentially illustrate a process of manufacturing the semiconductor package 1 according to an embodiment of the inventive concept.

Referring to FIG. 7A, in some embodiments, the plurality of first semiconductor chips 110 are stacked on the previously manufactured package substrate 200. The plurality of first semiconductor chips 110 are offset in the horizontal direction and stacked in a step structure. The plurality of first semiconductor chips 110 are arranged such that the first active surface 112 faces a direction away from the package substrate 200.

Referring to FIG. 7B, in some embodiments, an extension wire 140E is disposed on the package substrate 200. The extension wire 140E is formed by a wire bonding process together with the first bonding wire 130. Although FIG. 7B illustrates an embodiment in which the extension wire 140E is formed after the first bonding wire 130, embodiments are not necessarily limited thereto, and in other embodiments, a sequence of the processes on the first bonding wire 130 and the extension wire 140E differs.

The extension wire 140E is spouted from a capillary CP. The extension wire 140E extends vertically upward from the second upper surface connection pad 232 on the package substrate 200. As the extension wire 140E extends upward from the second upper surface connection pad 232, the wire ball 141 is formed that has a horizontal width greater than the thickness of the extension wire 140E. The wire ball 141 is integrally formed with the extension wire 140E and provides a contact with the second upper surface connection pad 232.

When the extension wire 140E has spouted to a predetermined length, the capillary CP cuts the extension wire 140E. The predetermined length is substantially the same as the distance from the second upper surface connection pad 232 to a second chip pad 124 of the second semiconductor chip 120 to be formed with reference to FIG. 7D. In some embodiments, the predetermined length is slightly less than the distance from the second upper surface connection pad 232 to a second chip pad 214 of the second semiconductor chip 120.

Referring to FIG. 7C, in some embodiments, a portion of the extension wire 140E is removed from the resultant process structure of FIG. 7B to form the vertical wire 140.

Referring to FIG. 7D, in some embodiments, a second semiconductor chip 120 is disposed on the uppermost first semiconductor chip 110T. The second semiconductor chip 120 includes the chip connection member 142B disposed on the second chip pad 124 of the second semiconductor chip 120.

Referring to FIG. 7E, in some embodiments, in the process of attaching the chip connection member 142B in FIG. 7D, the chip connection member 142B may melt by heating, and the shape of the chip connection member 142B may change. The chip connection member 142 extends along the side surface of the vertical wire 140 due to an adhesion force of the vertical wire 140. As a result, the chip connection member 142 has a shape in which the horizontal width thereof generally decreases away from the second chip pad 124.

As described above, when the length of the vertical wire 140 is less than the vertical distance from the second upper surface connection pad 232 to the corresponding second chip pad 124, as illustrated in FIG. 7E, the second chip pad 124 is not directly connected to the vertical wire 140, but the second chip pad 124 is connected to the vertical wire 140 by the chip connection member 142.

In another embodiment, as illustrated in FIG. 2C, when the length of the vertical wire 140 is greater than the vertical distance from the second chip pad 124 to the corresponding second upper surface connection pad 232, as illustrated in FIG. 7E, the second chip pad 124 is in direct contact with the vertical wire 140, but the vertical wire 140 has a curved shape.

Referring to FIG. 7F, in some embodiments, an encapsulating member 150 is formed on the package substrate 200 and surrounds the plurality of first semiconductor chips 110 and the second semiconductor chip 120. The plurality of external connection terminals 222 are respectively provided on a plurality of external connection pads 221 disposed on a lower portion of the package substrate 200.

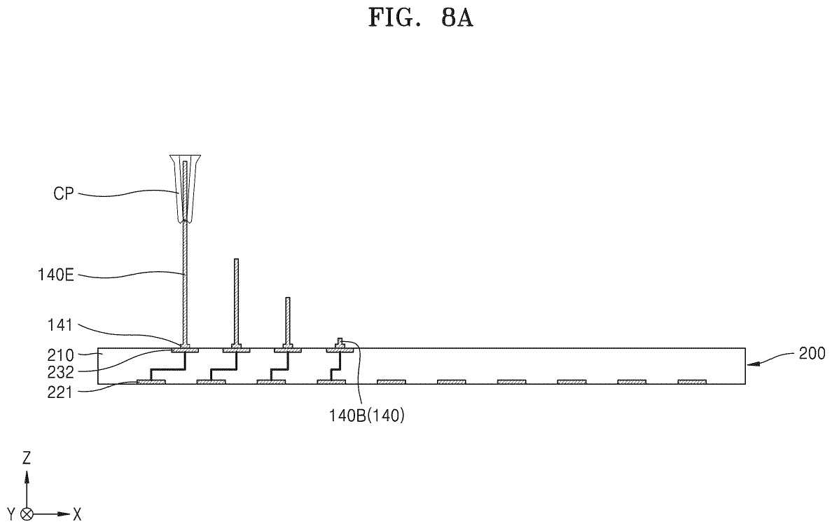

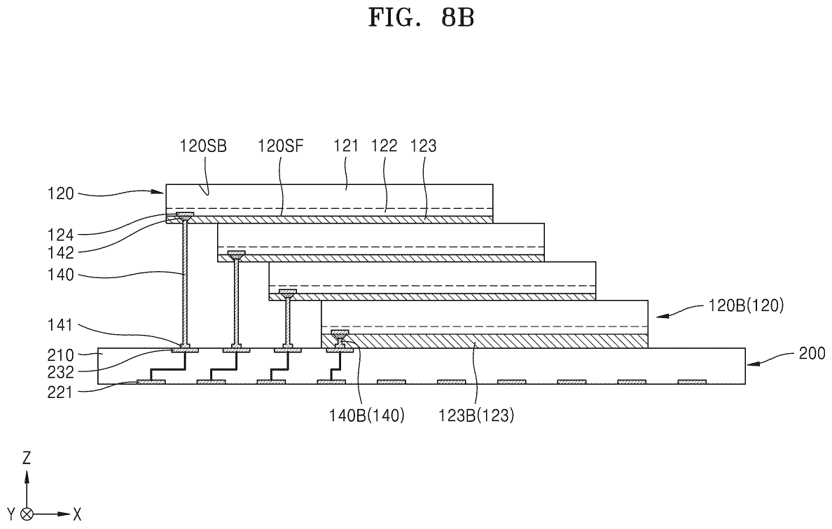

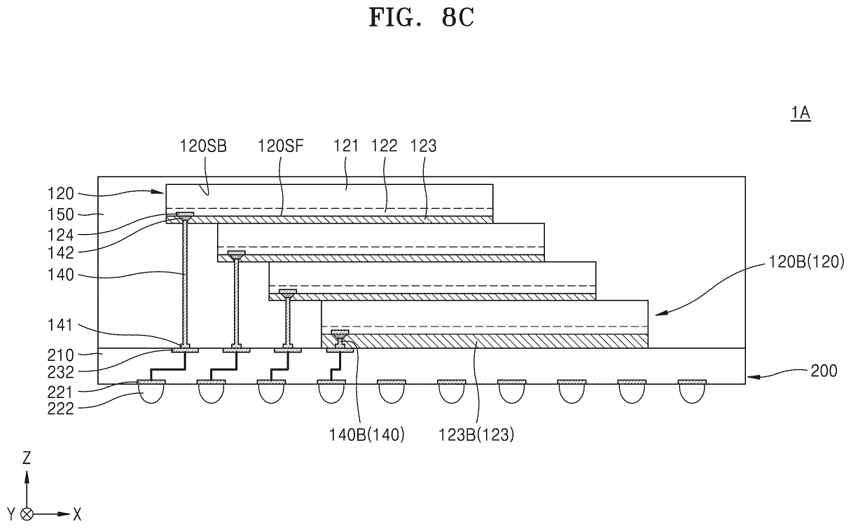

FIGS. 8A through 8C are cross-sectional views that sequentially illustrate a process of manufacturing the semiconductor package 1A according to an embodiment of the inventive concept.

Referring to FIG. 8A, in some embodiments, the extension wire 140E that corresponds to the second upper surface connection pad 232 is disposed on the package substrate 200 that includes the second upper surface connection pad 232 on the upper surface thereof. Similar to descriptions given with reference to FIGS. 7B and 7C, the extension wire 140E is spouted from the capillary CP, and the extension wire 140E extends vertically upward from the second upper surface connection pad 232 formed on the package substrate 200. In a similar manner, the wire ball 141 is formed, and the wire ball 141 forms one body with the extension wire 140E and provides a contact with the second upper surface connection pad 232.

When the extension wire 140E is spouted to a predetermined length by the capillary CP, the capillary CP cuts the extension wire 140E to form the vertical wire 140 as shown in FIG. 8B. The predetermined length is substantially the same as the distance from the second chip pad 124 of the second semiconductor chip 120 to the second upper surface connection pad 232.

Referring to FIG. 8B, in some embodiments, the plurality of second semiconductor chips 120 are stacked on the package substrate 200 in a step structure. The vertical wire 140 that corresponds to the second chip pad 124 in each of the plurality of second semiconductor chips 120 is connected by the chip connection member 142. Detailed descriptions of the form of the chip connection member 142 are substantially the same as the descriptions provided above.

Referring to FIG. 8C, in some embodiments, the encapsulating member 150 is formed on the package substrate 200 and surrounds the plurality of second semiconductor chips 120. The plurality of external connection terminals 222 are respectively disposed on the plurality of external connection pads 221 provided on a lower portion of the package substrate 200.

While embodiments of the inventive concept have been particularly shown and described with reference to drawings thereof. it will be understood that various changes in form and details can be made therein without departing from the spirit and scope of the following claims.

What is claimed is:

1. A semiconductor package, comprising:
a package substrate;
a first semiconductor chip disposed on the package substrate; and
a second semiconductor chip stacked in a step s on the first semiconductor chip,
wherein a first back surface of the first semiconductor chip faces the package substrate, the first back surface is opposite to a first front surface of the first semiconductor chip, and the first front surface of the first semiconductor chip includes a first active surface of the first semiconductor chip,
wherein a second front surface of the second semiconductor chip faces the first front surface and includes a second active surface of the second semiconductor chip,
wherein a first chip pad is disposed on the first front surface of the first semiconductor chip, and the first chip pad is connected to a first upper surface connection pad disposed on the package substrate, and
wherein a second chip pad is provided on the second front surface of the second semiconductor chip, and the second chip pad is connected to a second upper surface connection pad disposed on the package substrate by a vertical wire.

2. The semiconductor package of claim 1,
wherein the vertical wire comprises a wire ball,
wherein the wire ball is integrally formed with the vertical wire and is provided at one end of the vertical wire, and the wire ball is in contact with the second upper surface connection pad, and
wherein a chip connection member is disposed at another end of the vertical wire, and the chip connection member is disposed between the second chip pad and the vertical wire and connects the second chip pad to the vertical wire.

3. The semiconductor package of claim 2, wherein a horizontal width of the wire ball is greater than a horizontal width of the vertical wire.

4. The semiconductor package of claim 2,
wherein a first adhesive film is disposed on the first back surface of the first semiconductor chip,
wherein a second adhesive film is disposed on the second front surface of the second semiconductor chip, and
wherein at least a portion of a side surface of the chip connection member is surrounded by the second adhesive film.

5. The semiconductor package of claim 4, wherein
a horizontal width of the chip connection member decreases away from the second chip pad.

6. The semiconductor package of claim 5, wherein
the chip connection member penetrates the second adhesive film and protrudes downward from a surface of the second adhesive film, and the chip connection member surrounds a portion of a side surface of the vertical wire.

7. The semiconductor package of claim 1,
wherein a first height that is a maximum height of a first bonding wire from the package substrate is less than a second height that is a height of a second back surface of the second semiconductor chip from the package substrate, and
wherein the second back surface is opposite to the second front surface of the second semiconductor chip.

8. The semiconductor package of claim 7, further comprising
an encapsulating member disposed on the package substrate and that surrounds the first semiconductor chip and the second semiconductor chip,
wherein a vertical level of an upper surface of the encapsulating member from the package substrate is greater than the first height, and is equal to or greater than the second height.

9. The semiconductor package of claim 2, wherein
a length of the vertical wire is less than a vertical distance from the second upper surface connection pad from the second chip pad,
the vertical wire is spaced apart from the second chip pad, and
the chip connection member is disposed between the vertical wire and the second chip pad.

10. The semiconductor package of claim 2, wherein
a length of the vertical wire is greater than a vertical distance from the second upper surface connection pad from the second chip pad,
the vertical wire is in contact with the second chip pad, and
the vertical wire has a curved shape.

11. The semiconductor package of claim 10, wherein an intermediate portion of the vertical wire is offset in a lateral direction.

12. The semiconductor package of claim 1, wherein
a plurality of the first semiconductor chips are provided,
the plurality of first semiconductor chips are stacked in a step structure, and
the plurality of first semiconductor chips are respectively connected to a plurality of first upper surface connection pads by a plurality of first bonding wires.

13. A semiconductor package, comprising:
a package substrate; and
a plurality of semiconductor chips stacked in a step structure on the package substrate,
wherein a front surface of each of the semiconductor chips faces the package substrate, and
the front surface of each semiconductor chip comprises an active surface of the semiconductor chip,
wherein each of the plurality of semiconductor chips comprises a chip pad disposed on the front surface of the semiconductor chip,
wherein the package substrate comprises an upper surface connection pad disposed on an upper surface of the package substrate that faces the front surface of the semiconductor chip,
wherein each chip pad is individually connected to a corresponding upper surface connection pad by a vertical wire, and a wire ball is integrally formed with the vertical wire at one end of the vertical wire,
wherein another end of the vertical wire faces the chip pad, and a chip connection member is disposed at the another end of the vertical wire,
wherein the chip connection member connects the another end of the vertical wire to the chip connection member, and
wherein the upper surface connection pad that corresponds to the chip pad is disposed directly under the chip pad.

14. The semiconductor package of claim 13,
wherein the plurality of semiconductor chips comprise a lowermost semiconductor chip disposed at a lowermost level of the plurality of semiconductor chips,
wherein a first adhesive film is disposed between each of the plurality of semiconductor chips,
wherein a lowermost adhesive film is disposed between the lowermost semiconductor chip and an upper surface of the package substrate, and
wherein at least a portion of a side surface of the chip connection member is surrounded by the first adhesive film or the lowermost adhesive film.

15. The semiconductor package of claim 14, wherein a thickness of the lowermost adhesive film is greater than a thickness of the first adhesive film.

16. The semiconductor package of claim 14, wherein
a horizontal width of the chip connection member decreases away from the chip pad, and
the upper surface connection pad that corresponds to the chip pad overlaps at least a portion of the chip pad in a vertical direction.

17. The semiconductor package of claim 16, wherein
at least a portion of the chip connection member in contact with the first adhesive film penetrates the first adhesive film and protrudes downward from a surface of the first adhesive film, and the chip connection member in contact with the first adhesive film surrounds a portion of a side surface of the vertical wire, and
the chip connection member in contact with the lowermost adhesive film does not protrude downward from the lowermost adhesive film, and an entire side surface of the chip connection member in contact with the lowermost end adhesive film is surrounded by a lowermost adhesive film.

18. The semiconductor package of claim 13, wherein
a length of the vertical wire is less than a vertical distance from the corresponding upper surface connection pad to the chip pad, and
the vertical wire is spaced apart from the corresponding chip pad, and
the chip connection member is disposed between the vertical wire and the chip pad corresponding thereto.

19. The semiconductor package of claim 13, wherein
a length of the vertical wire is greater than a vertical distance from the upper surface connection pad to the chip pad,
the vertical wire is in contact with the chip pad, and
the vertical wire has a curved shape.

20. A semiconductor package, comprising:
a package substrate;
a first semiconductor chip disposed on the package substrate; and
a second semiconductor chip stacked in a step structure on the first semiconductor chip,
wherein a first back surface of the first semiconductor chip faces the package substrate and is opposite to a first front surface of the first semiconductor chip, and the first front surface of the first semiconductor chip includes a first active surface of the first semiconductor chip,
wherein a second front surface of the second semiconductor chip faces the first front surface of the first semiconductor chip, and the second front surface of the second semiconductor chip includes a second active surface of the second semiconductor chip,
wherein a first chip pad is disposed on the first front surface of the first semiconductor chip, and the first chip pad is connected to a first upper surface connection pad disposed on the package substrate by a first bonding wire,
wherein a second chip pad is disposed on the second front surface of the second semiconductor chip, and the second chip pad is connected to a second upper surface connection pad disposed on the package substrate by a vertical wire,
wherein the vertical wire comprises a wire ball,
wherein the wire ball is integrally formed as one body with the vertical wire at one end of the vertical wire, the wire ball is in contact with the second upper surface connection pad, and a horizontal width of the wire ball is greater than a horizontal width of the vertical wire,
wherein a chip connection member is disposed at another end of the vertical wire, and the chip connection member is disposed between the second chip pad and the vertical wire and connects the second chip pad to the vertical wire,
wherein a first adhesive film is disposed on the first back surface of the first semiconductor chip,
wherein a second adhesive film is disposed on the second front surface of the second semiconductor chip,
wherein at least a portion of a side surface of the chip connection member is surrounded by the second adhesive film, and a horizontal width of the chip connection member decreases away from the second chip pad, and
wherein a first height that is a maximum height of the first bonding wire from the package substrate is lower than a second height that is a height of a second back surface of the second semiconductor chip from the package substrate, and the second back surface is opposite to the second front surface of the second semiconductor chip.
